(19) United States
(12) Patent Application Publication
(10) Pub. No.: US 2004/0036636 A1
(43) Pub. Date: Feb. 26, 2004

(54) Tone-free dithering methods for sigma-delta DAC

(76) Inventors: Rifeng Mai, Sunnyvale, CA (US); Zezhang Hou, Cupertino, CA (US)

Correspondence Address: EMIL CHANG, LAW OFFICES OF EMIL CHANG, 674 JASMINE DRIVE, SUNNYDALE, CA, 94086, US

(21) Appl. No.: 10/417,879

(22) Filed: Apr. 16, 2003

Related U.S. Application Data
(60) Provisional application No. 60/405,984, filed on Aug. 26, 2002.

(51) Int. Cl. H03M 1/20; H03M 3/00

(52) U.S. Cl. 341/131; 341/143

(57) ABSTRACT

Tone-free dithering methods for sigma-delta digital-to-analog converters are disclosed. A dither signal having a frequency outside of the baseband frequency of a converter is provided to randomize the baseband noise floor of the converter such that there is no idle tone existing in the useful frequency range. In practice, the dither signal is combined with the input signal at the front end of a sigma-delta modulator. The dither signal may be a sinusoidal waveform (or other types of waveforms) and/or a DC level at a frequency outside of the baseband frequency range of the converter. The dither signal may be combined with the input signal either before or after an interpolator. The out of band dither signal breaks up the idle tones and does not affect the dynamic range of the converter. It can be used in a wide variety of applications requiring high fidelity and stability.

### CROSS REFERENCE

This application claims priority to a provisional application entitled “Tone-Free Dithering Scheme for Sigma-Delta DAC without Impairing Dynamic Range” filed on Aug. 26, 2002, having an application Ser. No. 60/405,984.

### FIELD OF INVENTION

The present invention generally relates to methods for digital-to-analog converters, and, in particular, sigma-delta digital-to-analog converters.

### BACKGROUND

Analog to digital converters (“ADC”) and digital to analog converters (“DAC”) used to code audio signals can achieve minimal signal degradation in a psychoacoustic sense when the noise floor is invariant with respect to input signal characteristics (up to the point of overload). Thus, noise modulation and distortion are forms of nonlinearity which are undesirable and, if possible, are to be avoided. Oversampling sigma-delta ADCs and DACs uses a modulation technique, often referred to as sigma delta modulator (“SDM”), to move quantization noise out of the signal band to achieve high resolutions and high linearity. Generally, for large-amplitude input signals (up to the point of overload), the linearity of the output is excellent. However, for small-amplitude signal, the output may include a tonal signal that is not in the input. This tonal signal is often referred to as idle tone. It is well known that low-order SDMs suffer from the idle tone issue, and it is generally believed that higher-order systems do not suffer from such nonlinear artifacts. Indeed, it is easy to show that a higher-order SDM is virtually free of obvious distortion tones above the noise floor for the low level sinusoidal inputs. However, if the input is zero or extremely low, a high-order SDM is still subjected to the problem of idle tone degradation.

Traditional techniques for preventing the idle tone problem is to add a low level noise at the input. This method is often referred to as dithering. This method, however, would increase the noise floor of the system. For applications where signal fidelity is critical, such as in hi-fi audio and hearing aid applications, prior art methods for adding noise has not been ideal.

For a sigma-delta ADC, the feedback loop runs in the analog domain where there are many Gaussian noise sources. Its output is less tonal even if the order of the sigma-delta is high. For a sigma-delta DAC, the feedback loop runs in the digital domain where there are no other noise sources other than the one embedded in the input. Thus, the idle tone problem here is more severe and needs to be eliminated.

FIG. 1 illustrates a general sigma-delta modulator, having an input combined with the feedback signal and the combined signal is filtered by loop filter H 12. The filtered signal is combined 14 with the dither signal 18 to generate a second combined signal to be quantized by the quantizer 16 to generate the output signal. It is a conventional dithering scheme applicable to both sigma-delta ADCs and DACs. The dither signal, usually a pseudo-random signal added to the input of the single-bit quantizer, is shaped by the sigma-delta modulation loop into noise to break up the idle tone. However, there are a certain disadvantages associated with the introduction of a dither signal. First, it reduces the dynamic range of the modulator, in part due to the increase in the total noise power within the loop. Second, it tends to cause the modulator loop to be less stable. For many applications where dynamic range is critical this approach is less desired. For example, referring to FIG. 1b, in hearing aids applications, a sigma-delta DAC can be used to convert an oversampled pulse code modulation (“PCM”) input signal into a one-bit pulse density modulation (“PDM”) code suitable for controlling a power switch 30 that drives a speaker 32. It would be desirable to use a sigma-delta modulator in this type of applications but the problems associated with the addition of a dither signal must be resolved.

FIG. 2a illustrates the detailed implementation of a conventional sigma-delta DAC with a pseudo random number generator added before the z-bit quantizer. Here, a third order transfer function with coefficients b1, b2, and b3 is used to represent the loop filter H. The basic transfer function for each integrator block is illustrated by FIG. 2b. The difference between the (x-bit) input signal and the first gain a1 62 is provided as (a y-bit) input to the first integrator 42. Similarly, the difference between the output of the first integrator 42 and the second gain a2 60 is provided as input to the second integrator 46. Then, the difference between the output of the second integrator 46 and the third gain a3 58 is provided as input to the third integrator 50. The output of the third integrator is combined with the dither signal 54 and quantized by the quantizer 56 to generate the output of this sigma-delta modulator.

Another method for eliminating the idle tone problem in a SDM is to cause the modulator to be chaotic, where noise-shaping zeros are moved outside the unit circle in the z-domain. See C. Dunn and M. Sandler, “Linearing Sigma-Delta Modulators using Dither and Chaos,” Proc. 1995 IEEE Int. Symp. On Circuits and Systems, pp625-628 (May 1995). This method is equivalent to causing the open-loop transfer function to be less stable to generate non-periodic output. However, the dynamic range penalties for this chaotic SDM are more severe than the method described above and are therefore less applicable for high fidelity systems.

The idle tone problem in a sigma-delta modulator can be easily demonstrated by applying a constant DC at its input. It can be shown that a strong idle tone exists at a frequency given by:

$${f}_{idle\_tone} = \frac{dc\_value}{{V}_{ref}} f sampling = dc\_value * f sampling \vert {V}_{ref} = 1 , DAC$$

For example, for a dc_value of 0.001FS, fsampling of 1 Mhz, and Vref at 1V, a clear idle tone will appear at 1 khz. DC components exist in many practical applications involving sigma-delta DACs. For example, it can be generated from an analog circuit or digital quantization errors. Assuming a DC component is less than 1/(2*OSR), where oversampling ratio (“OSR”) is defined as the ratio of sampling frequency to Nyquist frequency, it can be shown that a strong idle tone will be present in the baseband.

In reality, idle tone is less predictable because DC component sources are complicated and are always mixed with input signals. Furthermore, idle tone problem can arise from certain other low-level inputs, where the mechanism of the problem for low-level inputs is not well understood but it must be avoided.

Given the lacks of an effective solution for resolving the idle tone problem in sigma-delta modulators, it is therefore desirable to have novel methods for dithering sigma-delta DAC without impairing dynamic range and can overcome the problems of the prior art.

### SUMMARY OF THE INVENTION

It is therefore an object of the present invention to provide tone-free dithering methods for sigma-delta DACs without impairing dynamic range;

It is another object of the present invention to provide tone-free dithering methods for sigma-delta DACs without impairing stability; and

It is yet another object of the present invention to provide tone-free dithering methods for sigma-delta DACs where the frequency of the dither signal is outside of the baseband.

Briefly, a tone-free dithering method for sigma-delta DACs is disclosed. Generally speaking, a dither signal having a frequency outside of the baseband frequency of the sigma-delta DAC is provided to the sigma-delta DAC. The dither signal randomizes the baseband noise floor such that there is no idle tone in the useful frequency region. In application, the dither signal is combined with the input signal at the front end of a sigma-delta modulator. The dither signal may be a large sinusoidal waveform (or other types of waveforms) or a DC level at a frequency outside of the baseband. The dither signal may be combined with the input signal either before or after an interpolator. The out of band dither signal breaks up the idle tones and does not affect the dynamic range of the converter. It can be used in a wide variety of applications requiring high fidelity and stability.

An advantage of the present invention is that it provides tone-free dithering methods for sigma-delta DACs without impairing dynamic range;

Another advantage of the present invention is that it provides tone-free dithering methods for sigma-delta DACs without impairing stability; and

Yet another advantage of the present invention is that it provides tone-free dithering methods for sigma-delta DACs where the frequency of the dither signal is outside of the baseband.

### IN THE DRAWINGS

FIG. 1a illustrates a general circuit layout of a sigma-delta modulator with an added dither signal;

FIG. 1b illustrates an application of a sigma-delta DAC to generate a one-bit PDM stream to drive a power speaker;

FIG. 2a illustrates a detailed implementation of a conventional sigma-delta DAC with a pseudo random signal added before the z-bit quantizer;

FIG. 2b shows an illustration of a transfer function in the z-domain;

FIG. 3a illustrates the presently preferred embodiment of the present invention, a sigma-delta DAC that eliminates the idle tone problem;

FIG. 3b shows an illustration of a transfer function in the z-domain;

FIG. 3c illustrates a sinusoidal dither signal running at a frequency above the Nyquist frequency;

FIG. 4a illustrates an alternate embodiment of the present invention of a sigma-delta DAC that eliminates the idle tone problem;

FIG. 4b shows an illustration of a transfer function in the z-domain;

FIG. 4c illustrates a sinusoidal dither signal running at a frequency above the Nyquist frequency;

FIG. 5 illustrates the output spectrum of a sigma-delta DAC without the use of a dithering scheme;

FIG. 6 illustrates the output spectrum of a sigma-delta DAC using a high frequency sinusoidal waveform as the dither signal;

FIG. 7 illustrates the output spectrum of a sigma-delta DAC using a DC signal as the dither signal; and

FIG. 8 illustrates the output spectrum of a sigma-delta DAC using a high frequency sinusoidal waveform together with a DC offset as the dither signal.

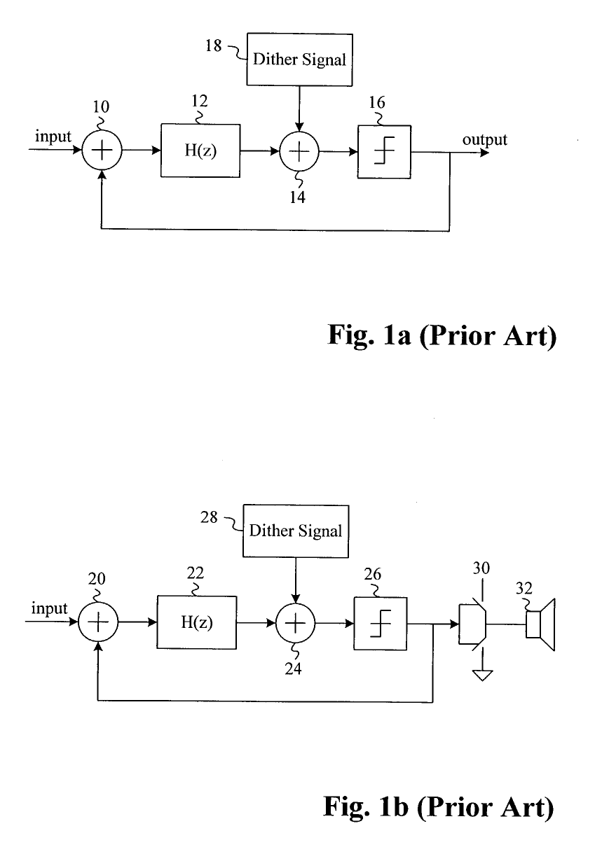

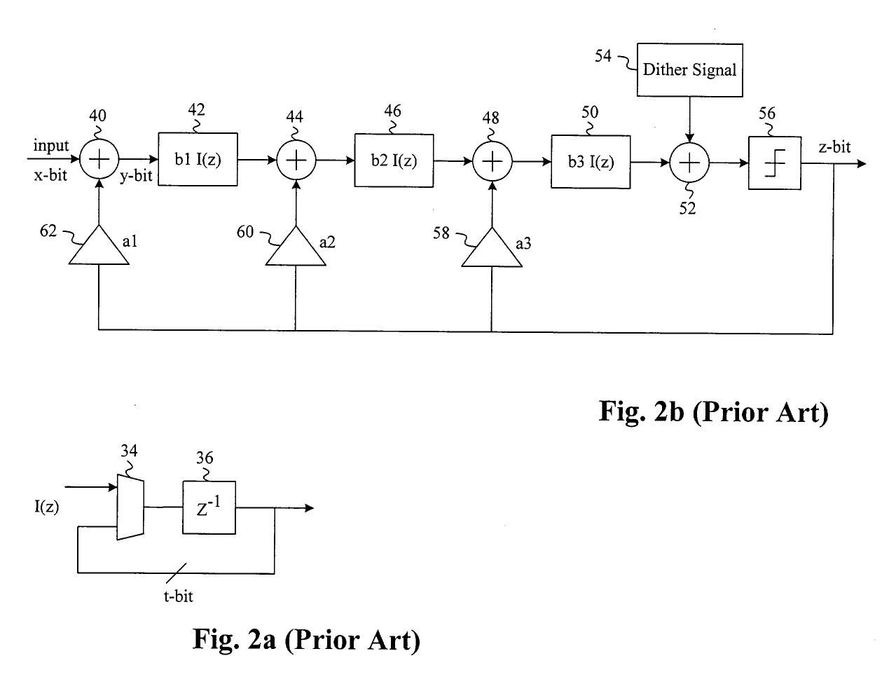

### DETAIL DESCRIPTION OF THE PREFERRED EMBODIMENTS

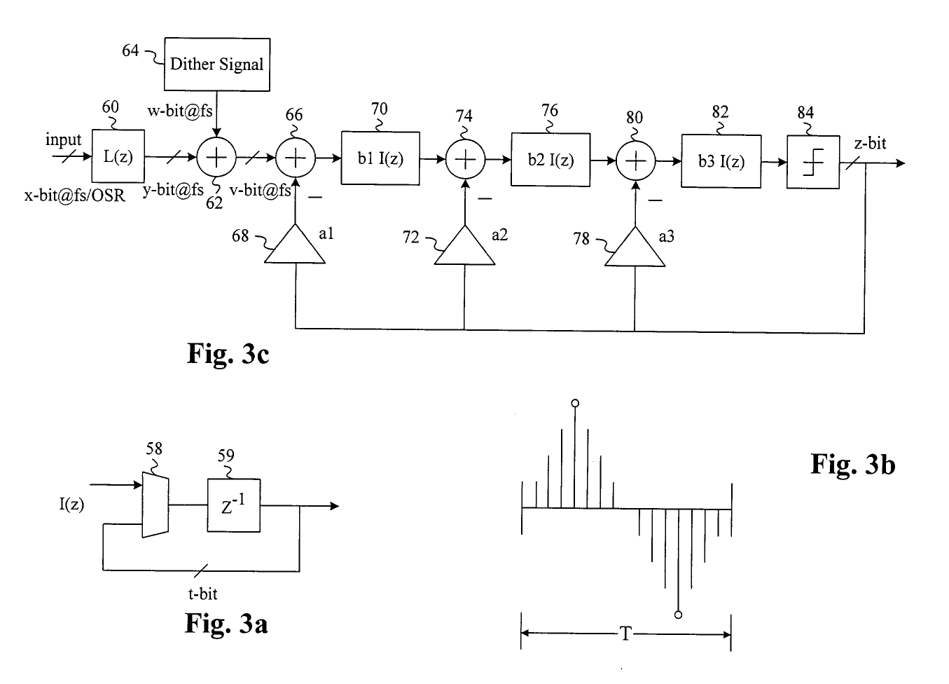

Referring to FIG. 3a, a presently preferred embodiment of the present invention, a tone-free dithering method, is disclosed. Here, the input signal (x-bit@fs/OSR) is interpolated by an interpolator 60 to generate a signal (y-bit@fs), which is combined with a dither signal (w-bit@fs) 64. The difference between the combined signal and the first gain a1 68 is provided as input (v-bit@fs) to the first integrator 70. Similarly, the difference between the output of the first integrator 70 and the second gain a2 72 is provided as input to the second integrator 76. Then, the difference between the output of the second integrator 76 and the third gain a3 78 is provided as input to the third integrator 82. The output of the third integrator 82 is quantized by the quantizer 84 to generate the output (z-bit) of this sigma-delta modulator. The basic transfer function for each integrator block (70, 76 and 82) is illustrated by FIG. 3c. Note that the present invention is applicable to n-order transfer functions, where n can be any positive integer. Further note that the interpolator of FIG. 3a is an optional step of the preferred embodiment of the present invention.

The dither signal in the preferred embodiment is a sinusoidal waveform (as illustrated by FIG. 3b) running at a frequency above the Nyquist rate. Here, dynamic range and linearity of the DAC is not compromised because the frequency of the dithering signal is outside of the baseband. The sinusoidal dither signal has an amplitude, Vp, where

$$Vp = \frac{1}{OSR} ,$$

and frequency, f_{dither}, where

$${f}_{dither} = \frac{m * fs}{OSR} ,$$

where m is a small integer number (e.g. m=4). OSR is the oversampling ratio, or

$$OSR = \frac{fs}{fN} ,$$

where f_{N} is the Nyquist frequency, and fs is the sampling rate of the DAC. Moreover,

$$T = \frac{OSR}{m * fs} , and$$

$$Vdc \geq \frac{1}{OSR} or 0.$$

In selecting m to determine f_{dither}, m is select in such manner such that

f_{dither}==zeros of H(z) if possible; or

f_{dither}==zeros of LPF(s) if possible.

In sum, the dither signal here is a large sinusoidal waveform having a frequency outside of the baseband and is inserted at the front of the sigma-delta DAC. The fact that the operating frequency of the sigma-delta DAC is much higher than the baseband frequency allows this to be a practical implementation. As shown, the amplitude and frequency of the dither signal can be 1/OSR and m*fs/OSR, respectively. For specific applications, the amplitude is determined according to the attenuation of the subsequent digital or analog filter. For example, if a noise outside of the baseband is not a concern, the amplitude can be changed to 2/OSR for more effective elimination of the idle tones.

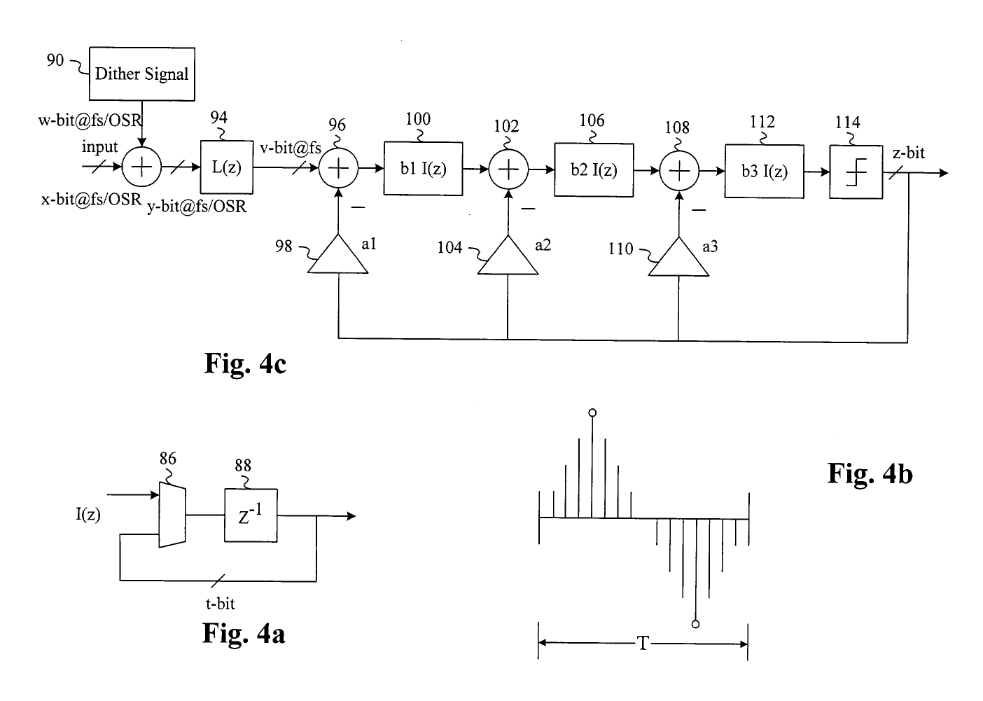

In yet another embodiment of the present invention, referring to FIG. 4a, the dither signal is added before the interpolator of a sigma-delta DAC. Here, input signal (x-bit@fs/OSR) is combined with the dither signal (w-bit@fs/OSR) 90 with the resulting output (y-bit@fs/OSR) provided to the interpolator 94 to generate an interpolated signal (v-bit@fs). The function of the interpolator is to convert signals from one sampling rate to a different sampling rate. The difference between the interpolated signal and the first gain a1 98 is provided as input to the first integrator 100. Similarly, the difference between the output of the first integrator 100 and the second gain a2 104 is provided as input to the second integrator 106. Then, the difference between the output of the second integrator 106 and the third gain a3 110 is provided as input to the third integrator 112. The output of the third integrator 112 is then quantized by the quantizer 114 to generate the output (z-bit) of this sigma-delta modulator. The basic transfer function for each integrator block (100, 106 and 112) is illustrated by FIG. 4c.

Referring to FIG. 4b, the dither signal here is a DC signal running at a frequency above the Nyquist rate. The idea is to add a DC dither signal before the linear interpolation filter, which converts a signal from a low sampling rate to a high sampling rate. The DC signal can be as large as 1/OSR when m=1. The goal here is to purposely generate an idle tone at a frequency outside of the baseband while randomizing baseband noise floor so there is no idle tone in the useful frequency region. Again, dynamic range and linearity of the DAC is not compromised because the dithering signal is outside of the baseband.

Note that the disclosure described herein has been referring to a sinusoidal waveform dither signal. It shall be understood by one skilled in the art that other types of waveforms can be used as well when appropriate, such as square waveforms, triangular waveforms, etc.

Further note that the above described schemes in applying dither signals can be turned-on when there is no signal or a small signal is detected at the input; and it can be turned-off when the input exceeds a pre-defined threshold level. Also, a hysteresis of the on/off transition can be used to avoid a frequent switching between the on and off modes.

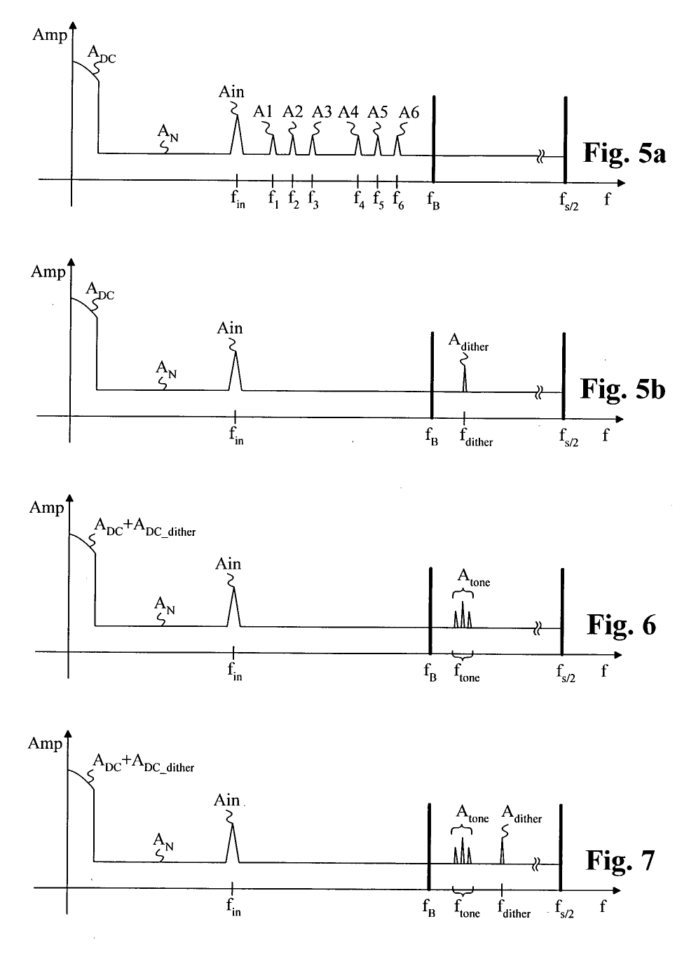

FIGS. 5-8 illustrate the resulting spectrum output when using different dithering signals. FIG. 5 illustrates the output spectrum of a DAC without a dithering scheme. Here, the input is a low-level sinusoid waveform with random noise and a DC offset. The amplitude of the DC offset is A_{dc}, Aᵢₙ is the amplitude of the baseband input signal level, A1-A6 are the idle tone signal amplitudes at f1-f6, respectively, f_{B} indicates the maximum input signal bandwidth, fs/2 is half of the sampling frequency, and An is the noise floor amplitude level. The range between f_{B} and fs/2 is outside of the baseband frequency range, which is also the range that does not affect user experience; this range can also be filtered out by subsequent filters.

FIG. 6 illustrates the output spectrum of a DAC when a dither signal is added at a frequency higher than f_{B}. Note that the idle tones now have been minimized or have disappeared. FIG. 7 illustrates the output spectrum of a DAC when a DC level is added as the dither signal. Note that Aₜₒₙₑ are the amplitudes of the idle tones caused by the DC dither signal and Fₜₒₙₑ are the frequencies of the idle tones caused by the DC dither signal. Note that the effect of the DC signal results in Aₜₒₙₑ being produce in a frequency range outside of the baseband range. FIG. 8 illustrates the output spectrum when the dither signal added is a sinusoidal waveform together with a DC offset. Therefore, there are both Aₜₒₙₑ and A_{dither} in the spectrum but at a frequency that would not impact user experience.

While the present invention has been described with reference to certain preferred embodiments, it is to be understood that the present invention is not to be limited to such specific embodiments. Rather, it is the inventor's contention that the invention be understood and construed in its broadest meaning as reflected by the following claims. Thus, these claims are to be understood as incorporating and not only the preferred embodiment described herein but all those other and further alterations and modifications as would be apparent to those of ordinary skilled in the art.

We claim:

1. A method for dithering a digital-analog converter, comprising the steps of:
combining an input signal and a dither signal to generate a first combined signal;
combining said first combined signal and an output signal to generated a second combined signal;
filtering said second combined signal; and
quantizing said filtered signal to generate said output signal.

2. A method as recited in claim 1 further including a step for interpolating said input signal to generate an interpolated signal and combining said interpolated signal and said dither signal to generate said first combined signal.

3. A method as recited in claim 1 wherein said converter having a baseband frequency range and said dither signal having a frequency outside said baseband frequency range.

4. A method as recited in claim 3 wherein said dither signal is a sinusoidal signal.

5. A method as recited in claim 1 wherein said dither signal is a DC signal.

6. A method as recited in claim 3 wherein said dither signal is a square wave signal.

7. A method as recited in claim 3 wherein said dither signal is a triangular wave signal.

8. A method as recited in claim 2 wherein said converter having a baseband frequency range and said dither signal having a frequency outside said baseband frequency range.

9. A method as recited in claim 8 wherein said dither signal is a sinusoidal signal.

10. A method as recited in claim 2 wherein said dither signal is a DC signal.

11. A method as recited in claim 8 wherein said dither signal is a square wave signal.

12. A method as recited in claim 8 wherein said dither signal is a triangular wave signal.

13. A method as recited in claim 1 wherein said output signal is amplified before combining with said first combined signal.

14. A method for dithering a digital-analog converter, comprising the steps of:
combining a dither signal and received input signal to generate a first combined signal;
interpolating said first combined signal;
combining said interpolated signal and an output signal to generated a second combined signal;
filtering said second combined signal; and
quantizing said filtered signal to generate said output signal.

15. A method as recited in claim 14 wherein said converter having a baseband frequency range and said dither signal having a frequency outside said baseband frequency range.

16. A method as recited in claim 15 wherein said dither signal is a sinusoidal signal.

17. A method as recited in claim 14 wherein said dither signal is a DC signal.

18. A method as recited in claim 15 wherein said dither signal is a square wave signal.

19. A method as recited in claim 15 wherein said dither signal is a triangular wave signal.

20. A method as recited in claim 14 wherein said output signal is amplified before combining with said first combined signal.

21. A digital-analog converter, comprising:
an adder for adding an input signal and a dither signal to generate a first combined signal;
a subtractor for subtracting an output signal from said first combined signal to generated a second combined signal;
a filter for filtering said second combined signal to generated a filtered signal; and
a quantizer for quantizing said filtered signal to generate said output signal.

22. A converter as recited in claim 21 further including an interpolator for interpolating said input signal to generate an interpolated signal before said adder and said adder for adding said interpolated signal and said dither signal to generate said first combined signal.

23. A converter as recited in claim 21 wherein said converter having a baseband frequency range and said dither signal having a frequency outside said baseband frequency range.

24. A converter as recited in claim 23 wherein said dither signal is a sinusoidal signal.

25. A converter as recited in claim 21 wherein said dither signal is a DC signal.

26. A converter as recited in claim 23 wherein said dither signal is a square wave signal.

27. A converter as recited in claim 23 wherein said dither signal is a triangular wave signal.

28. A converter as recited in claim 22 wherein said converter having a baseband frequency range and said dither signal having a frequency outside said baseband frequency range.

29. A converter as recited in claim 28 wherein said dither signal is a sinusoidal signal.

30. A converter as recited in claim 22 wherein said dither signal is a DC signal.

31. A converter as recited in claim 28 wherein said dither signal is a square wave signal.

32. A converter as recited in claim 28 wherein said dither signal is a triangular wave signal.

33. A converter as recited in claim 21 wherein said output signal is amplified before being subtracted by said first combined signal.

34. A digital-analog converter, comprising:
an adder for adding an input signal and a dither signal to generate a first combined signal;
an interpolator for interpolating said first combined signal to generate an interpolated signal;
a subtractor for subtracting an output signal from said interpolated signal to generated a second combined signal;
a filter for filtering said second combined signal to generated a filtered signal; and
a quantizer for quantizing said filtered signal to generate said output signal.

35. A converter as recited in claim 34 wherein said converter having a baseband frequency range and said dither signal having a frequency outside said baseband frequency range.

36. A converter as recited in claim 35 wherein said dither signal is a sinusoidal signal.

37. A converter as recited in claim 34 wherein said dither signal is a DC signal.

38. A converter as recited in claim 35 wherein said dither signal is a square wave signal.

39. A converter as recited in claim 35 wherein said dither signal is a triangular wave signal.

40. A converter as recited in claim 34 wherein said output signal is amplified before being subtracted by said interpolated signal.
